(19) United States
(12) Patent Application Publication
(10) Pub. No.: US 2002/0197807 A1
(43) Pub. Date: Dec. 26, 2002

(54) Non-self-aligned SiGe heterojunction bipolar transistor

(75) Inventors: Basanth Jagannathan, Stormville, NY (US); Shwu-Jen Jeng, Wappingers Falls, NY (US); Jeffrey B. Johnson, Essex Junction, VT (US); Robb A. Johnson, S. Burlington, VT (US); Louis D. Lanzerotti, Burlington, VA (US); Kenneth J. Stein, Newtown, CT (US); Seshadri Subbanna, Brewster, NY (US)

Correspondence Address: Michael E. Whitham, McGuireWoods, LLP, Suite 1800, 1750 Tysons Blvd., McLean, VA, 22102, US

(73) Assignee: International Business Machines Corporation, Armonk, NY

(21) Appl. No.: 09/885,792

(22) Filed: Jun. 20, 2001

(51) Int. Cl. H01L 21/331; H01L 21/8222

(52) U.S. Cl. 438/312; 438/320

(57) ABSTRACT

A method for making a non-self-aligned, heterojunction bipolar transistor includes forming extrinsic base regions with a PFET source/drain implant aligned with the polysilicon in an emitter stack but which are not directly aligned with an emitter opening defined in that stack. This is achieved by making the emitter pedestal wider than the emitter opening. This advantageously removes the dependency of alignment between the extrinsic base regions and the emitter opening, thereby resulting in fewer process steps, reduced thermal cycles, and improved speed.

### BACKGROUND OF THE INVENTION

1. Field of the Invention

This invention generally relates to the fabrication of semiconductor electronic integrated circuits, and more particularly to a method for making a non-self-aligned heterojunction biopolar transistor (HBT).

2. Description of the Related Art

The bipolar transistor is a basic element in integrated circuits because of its high-speed switching capability and current carrying capacity. Consequently, many improvements have been made to reduce the size and complexity of these devices while maintaining or even increasing their performance.

One type bipolar transistor, known as a heterojunction bipolar transistor (HBT), offers advantages over conventional junction bipolar transistors by providing a bandgap difference between its base and emitter regions. In an NPN transistor, this bandgap difference restricts hole flow from base to emitter, which, in turn, improves emitter-injection efficiency and current gain. The improved emitter-injection efficiency allows the use of low resistivity base regions and high resistivity emitter regions to create fast devices without compromising other device parameters. Thus, HBTs can realize high current gain while simultaneously having a low base resistivity and low emitter base junction capacitance.

Heterojunction bipolar transistors are usually formed from group III-V semiconductor materials. This is because these materials exhibit high electron mobility, and because many advanced crystal growth techniques are available for their formation including molecular beam epitaxy and metal organic chemical vapor deposition. Generally speaking, there are two types of heterojunction bipolar transistors. The first type uses wide band gap materials and is formed by growing, for example, GaP, SiC or amorphous silicon on the base. The second type uses narrow band gap materials and is formed by situating a SiGe alloy base between a silicon collector and a silicon emitter.

The second type of heterojunction bipolar transistors (SiGe HBTs) may be classified as either self-aligned or non-self-aligned. FIGS. 1(a)-1(j) show a series of steps used to make a conventional self-aligned HBT. In FIG. 1(a), an initial step includes forming an n⁺sub-collector region 2 in a silicon substrate 1. This is followed by the formation of shallow trench regions (STIs) 3, a reach-through layer 4 made from n⁺material and an n-silicon layer 5.

In FIG. 1(b), a series of layers are formed over the layer incorporating the STI and reach-through regions. These layers include a SiGe layer 6 approximately 0.05 to 0.3 um thick, an oxide layer 7 which is 0.01 to 0.015 um thick, a nitride layer 8 which is 0.08 to 0.03 um thick, a polysilicon layer 9 which is 0.03 to 0.06 um, a nitride layer 10 which is 0.08 to 0.15 um, and a tetraethyl orthosilicate (TEOS) layer 11 which is 0.2 to 0.4 um thick.

In FIG. 1(c), a resist layer 12 is formed on top of the TEOS layer in alignment with p-typed doped SiGe base layer 6 directly above n-region 5. The TEOS and second nitride layers are then patterned and etched back to polysilicon layer 9. This results in the formation of a stack 13 made of the portions of the TEOS and nitride layers underneath the resist layer 12.

In FIG. 1(d), the resist layer is removed and sidewall formations 14 and 15 made of an oxide are developed on stack 13. These sidewall portions function as masking layers for a subsequent implant step, which involves implanting a p-type dopant to a depth which includes the SiGe layer 6. These implanted ions form extrinsic p⁺base implants regions 16 and 17.

In FIG. 1(e), the sidewall formations and the TEOS layer are removed, thereby reducing the stack to only the underlying nitride layer.

In FIG. 1(f), the polysilicon layer is converted to an oxide using a known high-pressure thermal oxidation techniques. By thermally oxidizing the polysilicon layer, all of that layer except the portion 9 masked by the nitride is converted to silicon dioxide layer 18.

In FIG. 1(g), the nitride layer forming the stack is removed, and an opening 19 through the unconverted polysilicon is formed using an oxide layer 18 as the etch mask. Subsequently, the underlying nitride layer at the opening is etched to expose the oxide layer 7.

FIG. 1(h), a collector pedestal implant 20 for a high ƒ_{T} device is formed beneath the p-type SiGe base in n-region 5. Implant 20 is self-aligned to the emitter opening and extrinsic base implant regions and is an n-type implant. (The variable ƒ_{T} is the cutoff frequency of the transistor and is an important figure of merit for high-frequency and microwave transistors. It is defined as the frequency at which the common emitter short-circuit current gain is unity. The cutoff frequency is inversely proportional to the total emitter-to-collector delay time t_{ec}. As a figure of merit, it is indicative of the raw speed which device is capable of operating. To obtain a higher ƒ_{T}, the transistor should have a very narrow base, a very narrow collector, and low capacitances.)

In FIG. 1(i), rapid thermal oxidation is performed, followed by deposition of polysilicon layer 21 which is subsequently doped with an n-type dopant during an ion implantation process. This layer is then covered with a nitride layer 22 for a short emitter rapid thermal anneal (RTA) process.

Finally, in FIG. 1(j), a series of photoresist and etch steps result in the formation of a self-aligned, heterojunction bipolar transistor with a collector 20, extrinsic base regions 16 and 17, an intrinsic base region 23, and an emitter region 24 with a nitride cap 25. Finally, emitter, base, and collector contacts and metallization will be formed.

From the above, it is evident that the conventional self-aligned process for forming heterojunction bipolar transistors is complicated and time consuming. This is largely attributable to the formation of an emitter pedestal in the self-aligned process. More specifically, the formation of a dielectric emitter pedestal and a self-aligned extrinsic base structure shown in FIG. 1(j) requires additional pedestal reactive ion etching (RIE), spacer deposition and etch, oxide strip, high-pressure oxidation, and emitter opening RIE steps before the emitter poly deposition step may be performed. These steps increase the time of manufacture of the HBT and thus have proven to be very inefficient.

A need therefore exists for a method of making an HBT device which is faster and more cost-efficient than conventional methods, and more specifically one which is not self-aligned in the traditional sense and does not require the formation of an emitter pedestal.

Methods for forming non-self-aligned heterojunction bipolar transistors have been proposed. U.S. Pat. No. 5,656,514 discloses one such HBT which is formed from epitaxially grown silicon emitter and base layers which are uniformly doped. In this device, the emitter dopant concentration is lower than the concentration of the base, contrary to more traditional (homojunction) bipolar junction transistors. This permits the use of a thinner base for a given base resistance and lowers the base-emitter junction capacitance and electric field.

HBTs of the type disclosed in the '514 patent also have drawbacks. Specifically, these HBTs typically use non-self-aligned base contact and mesa isolations. Consequently, their performance is limited. There is, therefore, also a need for a heterojunction bipolar transistor which is formed without contact and mesa isolation in order to realize increased performance.

### SUMMARY OF THE INVENTION

It is one object of the present invention to provide a method for making an heterojunction bipolar transistor which is faster, simpler, and more cost efficient than conventional methods.

It is another object of the present invention to achieve the aforementioned object by forming a non-self-aligned emitter without using traditional emitter pedestal and self-aligned extrinsic base structures which complicate conventional self-aligned HBT formation methods, and which avoids the formation of contact and mesa isolation structures which impair the performance of conventional non-self-aligned HBT devices.

It is another object of the present invention to provide a method for making an HBT transistor having extrinsic base regions which are aligned with an emitter polysilicon region but which is not directly aligned with an emitter opening of the transistor.

It is another object of the present invention to provide a method for making a heterojunction bipolar transistor which has reduced transient enhanced diffusion of the dopants used to form the emitter and base regions, which translates into much sharper and narrower doping profiles compared with conventional HBT formation methods. As a result, the transistor structure of the present invention may advantageously be tailored for high-speed performance.

It is another object of the present invention to a method for making a heterojunction bipolar transistor which performs low thermal-cycle processing, which, in turn, allows the present method to use thin low-temperature epitaxy (LTE) layers in the formation of base and collector regions. Use of thin LTE layers for these regions increases speed of the transistor and, further, leads to a lowering of the overall topography of the device, making mid-end-of-line (MEOL) processes such as emitter, base, and collector contact opening much easier.

The foregoing and other objects of the invention are achieved by providing a method for making a non-self-aligned, heterojunction bipolar transistor in accordance with steps that include depositing a first SiGe polysilicon layer over shallow trench regions and a single crystalline SiGe intrinsic base region over collector region, forming an oxide layer over the first SiGe polysilicon layer, forming a first nitride layer over the oxide layer, etching an emitter opening through the first nitride layer, filling the emitter opening with a second polysilicon layer, forming an emitter pedestal from the second polysilicon layer and the first nitride layer, and implanting source/drain regions into at least the first SiGe polysilicon layer with a PFET source/drain implant which is compatible to a BiCMOS process. These implanted SiGe polysilicon regions will be the extrinsic base regions. In accordance with the invention, the emitter pedestal is made to have a width which is wider than the emitter opening. As a result, the extrinsic base regions are self-aligned with the second polysilicon layer in the emitter pedestal, but are not directly aligned with the emitter opening.

Removing the dependency of alignment between the base regions and the emitter opening produces several advantageous effects, not the least of which is a substantial reduction in the number of process steps used to make the transistor. More specifically, by forming the non-self-aligned HBT of the present invention, formation of the complicated and time consuming emitter stack and extrinsic base structure conventionally used is avoided. Instead of five layers, the emitter stack of the invention now includes, in one embodiment, only oxide, nitride, and TEOS layers. This fewer number of layers reduces process time, cost, and complexity.

Also, in-between LTE base and emitter formation, the conventional self-aligned process requires emitter pedestal formation, extrinsic base sidewall dep/etch, extrinsic base implant, high pressure oxidation, and emitter opening. In contrast, the present invention includes only an emitter stack formation and an emitter opening. This advantageously serves to produce a faster and more cost-efficient HBT device. Furthermore, the extrinsic base implant may now be shared with p-type field effect transistor (PFET) source and drain implant, which further simplifies the process.

To form an even more efficient device, photo overlay and critical dimension tolerances used to form the emitter pedestal may be controlled to ensure that the T-shaped polysilicon layer in the pedestal has equal lengths on both of its sides. This translates into equal base resistances under the emitter, and by minimizing the width of the pedestal these resistances may commensurately be minimized. According to one aspect of the invention, the reach-through collector, emitter, and extrinsic base implant regions of the transistor can be contacted mid-end-of-line processes such as planarization polishing and a contact etch opening process. Finally, the metallization can be formed on the contacts.

### BRIEF DESCRIPTION OF THE DRAWINGS

FIGS. 1(a)-(j) illustrate a conventional method for making an HBT device which includes the following:

FIG. 1(a) is a diagram showing the formation of n-region and STI regions on a layer containing a sub-collector region;

FIG. 1(b) is a diagram showing the formation of various oxide and semiconductor layers on the structure in FIG. 1(a);

FIG. 1(c) is a diagram showing the formation of a pedestal capped with a resist layer on the upper-most oxide layer in FIG. 1(b);

FIG. 1(d) is diagram showing after the resist strip, the formation of sidewall spacers on the pedestal shown in FIG. 1(c);

FIG. 1(e) is a diagram showing the formation of extrinsic base regions which are self-aligned as a result of the nitride layer of the spacers of the pedestal;

FIG. 1(f) is a diagram showing the conversion of polysilicon into an oxide layer;

FIG. 1(g) is a diagram showing the formation of an opening prior to a collector implant step;

FIG. 1(h) is a diagram showing the formation of the collector implant;

FIG. 1(i) is a diagram showing the step of filling the opening with polysilicon which is subsequently doped with n-type dopant; and

FIG. 1(j) is a diagram showing the final HBT transistor after emitter and extrinsic base photomasking and etching.

FIG. 2 illustrates steps included in a preferred embodiment of the method of the present invention, which includes the following:

FIG. 2(a) is a diagram showing initial steps of a preferred embodiment of the present invention, including the formation of a sub-collector region in a silicon substrate followed by the deposition of a number of layers including a SiGe layer and a masking layer on a surface of the substrate;

FIG. 2(b) is a diagram showing the formation of an opening in which an emitter of the transistor will be formed;

FIG. 2(c) is a diagram showing the formation of a collector pedestal implant;

FIG. 2(d) is a diagram showing the formation of doped polysilicon in the opening which forms the emitter, along with a nitride layer cap;

FIG. 2(e) is a diagram showing an emitter polysilicon pedestal formed in accordance with the present invention;

FIG. 2(f) is a diagram showing the deposition of a photoresist material used as a first step in forming extrinsic base regions of the transistor;

FIG. 2(g) is a diagram showing the implantation of the extrinsic base regions of the transistor using nitride-capped emitter silicon pedestal and photoresists as a mask;

FIG. 2(h) is a diagram showing base resistances of a transistor formed in accordance with the present invention; and

FIG. 2(i) is a diagram showing the formation of mis-alignment between the emitter polysilicon and the extrinsic base regions, which results in altering the base resistances.

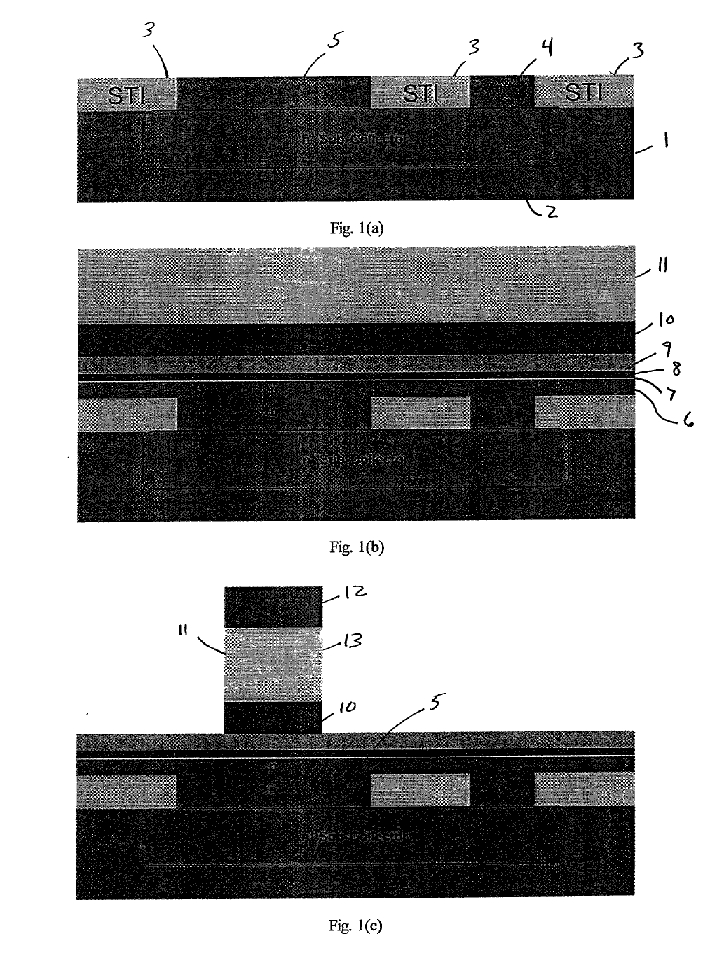

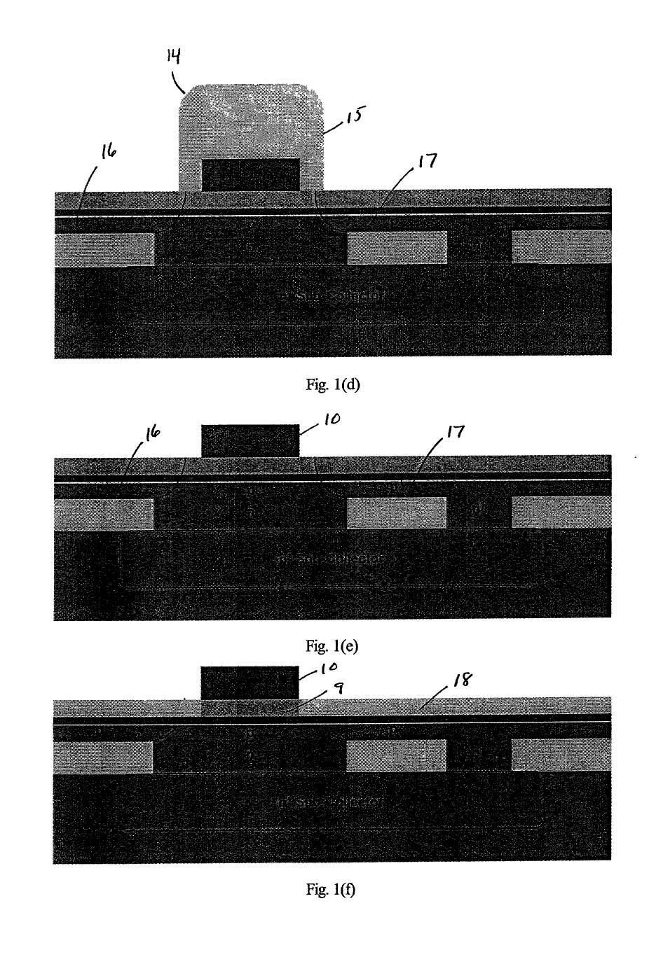

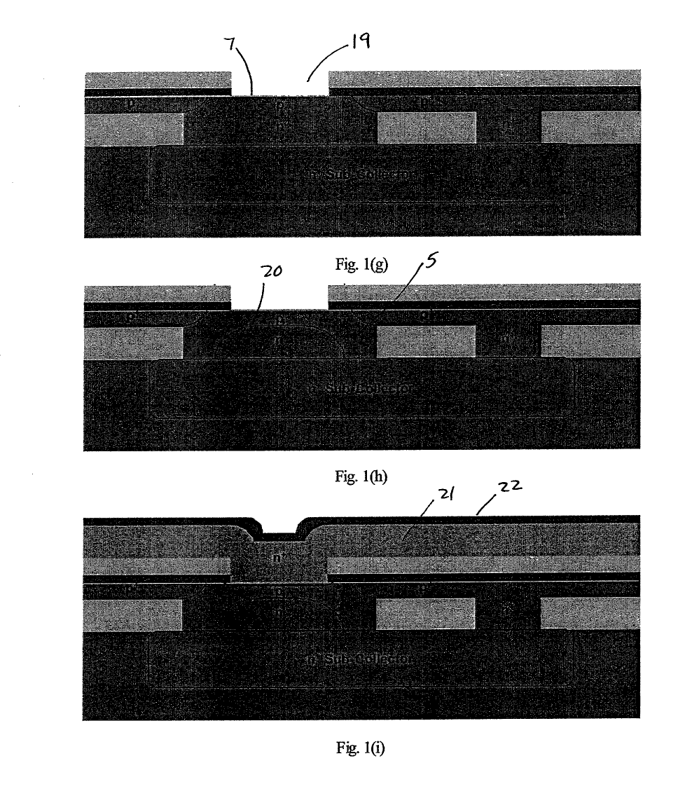

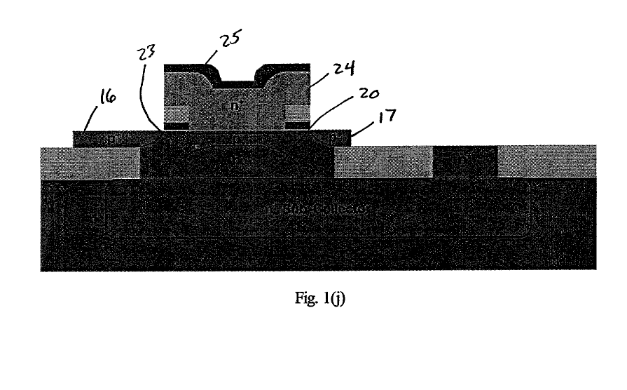

### DESCRIPTION OF THE PREFERRED EMBODIMENTS

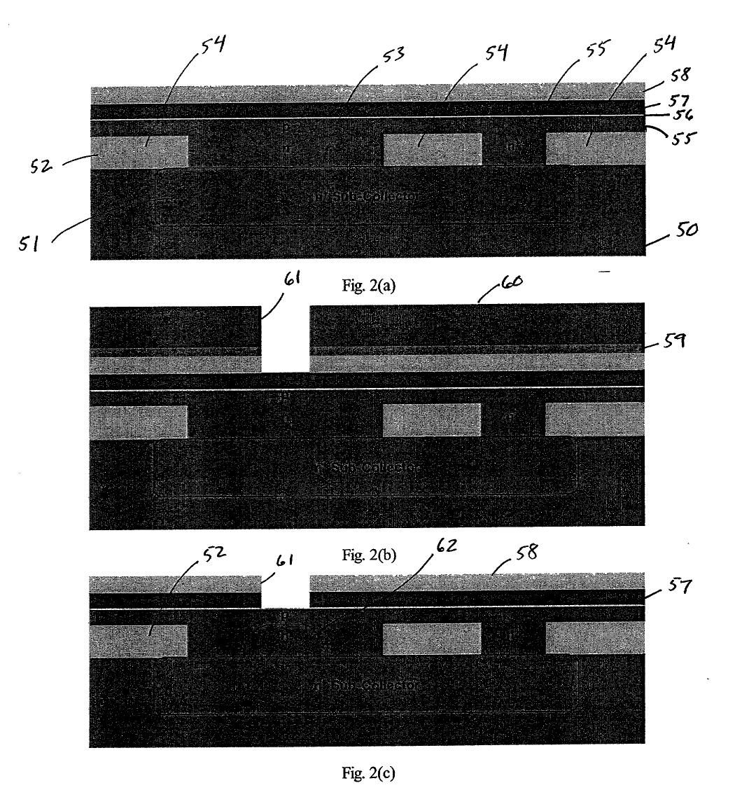

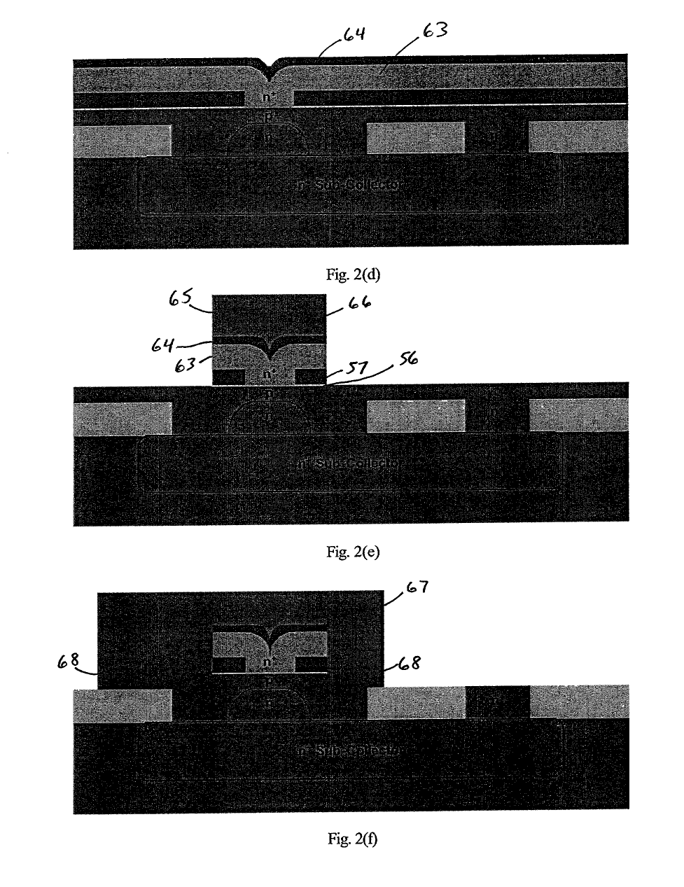

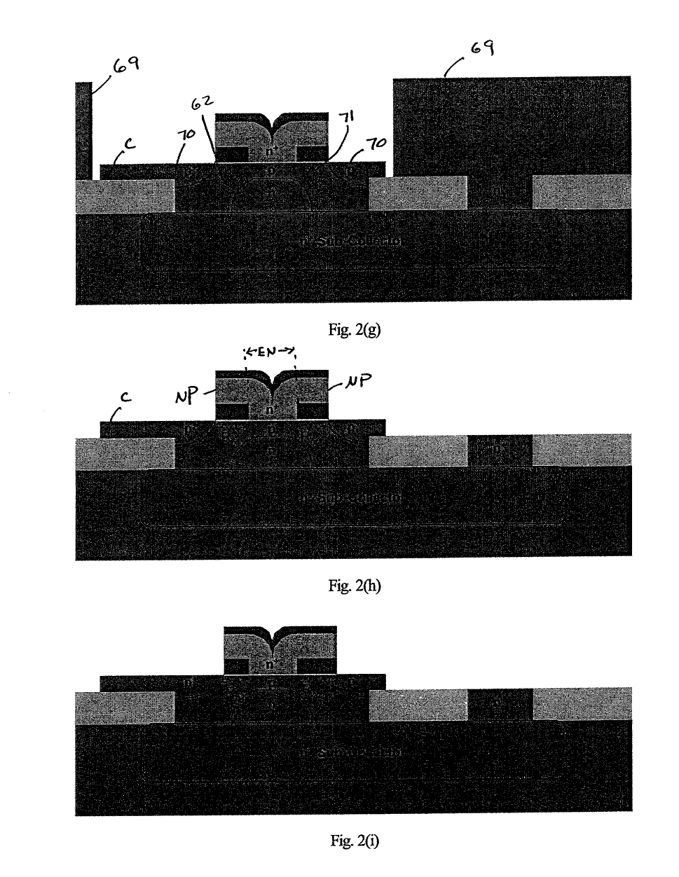

Referring to FIG. 2(a), a preferred embodiment of the method of the present invention includes as an initial step forming an n⁺sub-collector region 51 in a silicon substrate 50. A layer 52 is then formed over the sub-collector. This layer includes an n⁻epitaxial layer 53, shallow trench isolation (STI) regions 54, and an n⁺reach through region 55. Sub-collector layer 51 and reach through layer 55 may be formed using known techniques (e.g., n-type ion implantation), and the STI regions may be formed by a process which includes a trench etch, trench fill, and planarization polishing.

A number of layers are formed on layer 52, preferably over the n-epitaxial silicon layer 53. These layers include a SiGe layer 55 of p-type conductivity, abase oxide layer 56, a nitride layer 57, and a TEOS hard mask layer 58. Preferably, the SiGe layer is approximately 0.05-0.3 um thick, the oxide layer is 0.01-0.015 um thick, the nitride layer is 0.04 to 0.07 um thick and is made using a rapid thermal chemical vapor deposition (RTCVD) or a plasma enhanced chemical vapor deposition (PECVD) process, and the TEOS layer is 0.05 to 0.08 um thick and is made by known processes such as low-pressure chemical vapor deposition (LPCVD) or plasma enhanced chemical vapor deposition (PECVD). The thicknesses given above are only preferred values. As those skilled in the art will appreciate, other thicknesses may be used if desired.

In FIG. 2(b), an anti-reflection coating (ARC) layer 59 and a resist layer 60 are formed on the TEOS hard mask layer by a standard emitter opening mask. An emitter opening 61 is then formed at the location where the emitter of the transistor will be formed. This opening is formed, first, by etching through the ARC layer and then the TEOS layer to expose the underlying nitride layer which serves as an etch stop. The resist and ARC layers are then stripped, and the TEOS layer serves as an etch mask for subsequent nitride etch. Preferably, the etch chemistry for the ARC opening is CF₄ or N₂/O₂, and for the TEOS layer etch C₂F₆ and N₂ chemistry is used. CH₃F/CO₂ may be used for the nitirde etch.

In FIG. 2(c), the resist is stripped using a plasma etch process. The TEOS layer is then used as a hard mask to etch the nitride layer using a CH₃F/CO₂ etching process. This process is preferably performed at a lower power to ensure no focus beam at the edge of emitter opening. The nitride-to-oxide etch selectivity in CH₃F/CO₂ is reasonably high. This timed nitride etch stops at the base oxide layer. A pedestal implant 62 is then formed in n-type region 52. The pedestal implant is preferably formed from n-type dopant and serves as the collector of the transistor.

The implant is self-aligned in the sense that the remaining portion of opening 61 controls the width of the implant region.

In FIG. 2(d), the TEOS layer is stripped along with the base oxide layer using a wet dilute HF process. A layer of polysilicon 63 is then formed over the surface of the entire structure, including in the opening 61. This polysilicon layer may be an in-situ n-type doped polysilicon layer or may be implanted with an n-type dopant to form an n⁺region that will serve as the emitter of the transistor of the present invention. The polysilicon layer may also be a furnace polysilicon layer or an RTCVD polysilicon layer. A thick nitride protect layer 64 is formed over the doped-polysilicon using, for example, a PECVD process. Preferably, the polysilicon layer is 0.1-0.2 um and the nitride layer is 0.15-0.3 um.

In FIG. 2(e), it is lithographically patterned and etched. The patterning is performed by applying a photoresist layer 65 over the nitride layer at a width which corresponds to a desired width of the emitter, which as shown includes portions of the underlying nitride layer 57. Exposed portions of the nitride protect layer 64, polysilicon layer 63, nitride layer 57 are etched away using reactive ion etching.

Finally, the base oxide layer 56 is etched away using, for example, a wet HF process. This process is preferable because it will remove the oxide but leave the nitride, polysilicon, and SiGe layer intact. The etch stops at the SiGe layer, leaving an emitter pedestal 66.

In FIG. 2(f), extrinsic base regions of the transistor are formed in accordance with steps that include coating a photoresist material 67 so that the edges 68 of the resist stop on the underlying STI regions as shown. The exposed portions of the polysilicon SiGe layer 56 are then removed with an HBr/HeO₂ process, leaving only the portion of the SiGe layer protected by the photoresist material.

In FIG. 2(g), the photo resist material for the PFET source and drain implants are defined and once again the emitter stack is exposed. Then, resist layers 69 are formed on either side of the emitter pedestal spaced a predetermined distance from the remaining SiGe layers. The photo resist material is defined by a standard litho developing process. In FIG. 2(g), layer 69 is implant blocking photoresist. The spacing between layers 69 and the SiGe layers should be large enough for the base contact to form, typically 1.1-1.5 um.

Remaining portions of the SiGe layers and a portion of the underlying n-type region 52 are implanted with p-type dopant to form extrinsic p⁺base implant regions 70. These implant regions are advantageously aligned using the nitride-capped emitter stack as a mask. Preferably, PFET source/drain implants are used for the extrinsic base doping rather than a dedicated implant. Using PFET source/drain implants advantageously saves time and money because, with shared PFET source/drain implants in a BiCMOS process, there is no need for a separate extrinsic implant. Intrinsic base region 71 is disposed between the extrinsic base regions. (In the figure, the left source/drain (extrinsic base) implant is shown to be longer than the right source/drain (extrinsic base) implant. The widened area is provided as a contact region C. Those skilled in the art can appreciate that the contact region may be placed on the right source/drain (extrinsic base) implant, if desired, or both implants may be of the same length).

In FIG. 2(h), the photoresist layers 69 are removed using a plasma etching process. As shown, there is perfect alignment between the emitter polysilicon (NP) to emitter opening (EN). Using nitride capped emitter polysilicon as a mask for extrinsic base implant will produce extrinsic base regions aligned to the emitter polysilicon, but not necessarily aligned to the emitter opening. The alignment between the emitter polysilicon and emitter opening is now dependent on lithography process tolerance and etch bias. This may be explained in greater detail as follows.

The conventional self-aligned transistor has the extrinsic base self-aligned to the emitter opening level because the emitter pedestal sidewall provides a fixed symmetric spacing away from the emitter region. In contrast, the present invention has an extrinsic base aligned directly to the emitter polysiclicon but not necessarily directly aligned to emitter opening because the lithographic overlay of the emitter polysilicon and emitter opening is never ideal due to wafer, lens, and tool distortions. Therefore, the present invention is a non-self aligned transistor compared to the conventional self-aligned transistor.

In FIG. 2(h), the extrinsic base resistances under emitter polysilicon R_{b1} and R_{b2} can be made equal as long as there is a good alignment between emitter polysilicon and emitter opening. The total base resistance depends on value of R_{b1} and R_{b2} which can be adjusted by the NP emitter polysilicon size. By shrinking the emitter polysilicon (NP) size, the contribution from R_{b1} and R_{b2} can be made small and the total base resistance can be reduced.

FIG. 2(i) illustrates how the extrinsic base (PFET source/drain) implants of the present invention may be aligned to the emitter polysilicon but not aligned to the EN emitter opening. This mis-alignment, which also occurs between the emitter polysilicon and emitter opening, causes R_{b2} to be larger than R_{b1}. This is undesirable because it negatively impacts the performance of the transistor. The extrinsic base resistances under the emitter polysilicon R_{b1} and R_{b2} may be controlled by tightening the photo tolerance between the emitter polysilicon and the emitter opening and can be reduced by shrinking the emitter polysilicon size. The extrinsic base resistance under the emitter polysilicon R_{b1} and R_{b2} should be made as small as possible by shrinking the emitter polysilicon (NP) size. This will result in minimizing the misalignment and thus improving the performance of the transistor. (Both the emitter opening EN level and emitter polysilicon NP level are aligned to the previous shallow trench ST level. The mis-alignment between NP-EN is the total mis-alignment from EN-ST and NP-ST levels. To minimize the mis-alignment, the photo tolerance and develop bias has to be tightened in each level.)

To make transistor run faster, it is desirable to make the emitter, base, and collector narrower compared to the previous generation. Low-temperature epitaxy (LTE) and emitter polysilicon thickness may be scaled down from generation to generation.

The preferred embodiment of the method of the present invention may be modified in a number of ways. For example, the 0.04-0.06 um RTCVD nitride layer may be replaced by a 0.05-0.07 um PECVD nitride layer to further reduce thermal cycle. This 0.05-0.07 um nitride will be reduced to 0.04-0.06 um after NP oxide strip to maintain a desired level of parasitic capacitance. The lower the total thermal cycle, the less the dopants outdiffuse. The base is narrower and thus the base-transit time is reduced and the speed of the transistor is higher.

The method of the present invention, as described above, represents an improvement over conventional methods in a number of respects. Specifically, the present method produces a heterojunction bipolar transistor which is non-self-aligned in its extrinsic base areas. As a result, no complicated emitter pedestal, spacer deposition and etch, and high-pressure oxidation steps are required as is the case with conventional methods. This further reduces overall thermal cycle and minimizes base and collector widths required for a high speed transistor.

In the device formed by the method of the present invention, the extrinsic base is no longer self-aligned to the emitter opening as is the case in the conventional self-aligned transistor. The extrinsic base is directly aligned the emitter polysilicon which is not directly aligned to emitter opening level.

Other modifications and variations to the invention will be apparent to those skilled in the art from the foregoing disclosure. Thus, while only certain embodiments of the invention have been specifically described herein, it will be apparent that numerous modifications may be made thereto without departing from the spirit and scope of the invention.

We claim:

1. A method for making a heterojunction bipolar transistor, comprising:
(a) depositing a first polysilicon layer over shallow trench regions and a single crystalline SiGe intrinsic base region over a collector region;
(b) forming an oxide layer over the first polysilicon layer;
(c) forming a first nitride layer over the oxide layer;
(d) etching an opening through the first nitride layer, said opening corresponding to an emitter opening of said transistor;
(e) filling said emitter opening with a second polysilicon layer;
(f) forming an emitter pedestal from the second polysilicon layer and the first nitride layer, said emitter pedestal having a width which is wider than said emitter opening; and
(g) implanting source/drain implant regions into at least the first polysilicon layer, said source/drain implant regions being self-aligned with the second polysilicon layer in said emitter pedestal.

2. The method of claim 1, wherein the second polysilicon layer is in the shape of a T, with respective portions overlapping the first nitride layer.

3. The method of claim 2, wherein said step of forming said emitter pedestal includes making a length of the first SiGe polysilicon layer on one side of said emitter pedestal and a length of the first SiGe polysilicon layer on another side of said emitter pedestal to be different lengths, and wherein the side with large length will be used as base contact.

4. The method of claim 1, wherein the first polysilicon layer is an SiGe layer.

5. The method of claim 4, wherein said SiGe layer is less than 0.15 um thick.

6. The method of claim 1, wherein said oxide layer is a high-pressure thermal oxide layer.

7. The method of claim 1, wherein said collector region is an n-epitaxy region on top of a sub-collector region.

8. The method of claim 1, wherein said step of forming said emitter pedestal includes making a length of the second polysilicon layer on one side of said emitter pedestal at least substantially equal to a length of the second polysilicon layer on another side of said emitter pedestal, said substantially equal lengths causing said transistor to have equal base resistances on said one side and said another side of said emitter pedestal.

9. The method of claim 1, wherein said source/drain implant regions are extrinsic base regions.

10. The method of claim 1, wherein said step of forming said emitter opening includes:
forming a TEOS layer over the first nitride layer;
forming an ARC layer over the TEOS layer;
forming a resist over the ARC layer;
developing the resist layer and forming patterns on the ARC layer;
etching through selective portions of the ARC layer and the TEOS layer; and
stripping the resist and ARC layers, wherein the TEOS layer is a hard mask to etch the nitride layer to form said emitter opening.

11. The method of claim 1, wherein said step of forming said emitter pedestal includes:
forming a second nitride layer over the second polysilicon layer;
forming a photoresist over the second nitride layer; and
etching away the second nitride layer, the second polysilicon layer, and the oxide layer except in a region underlying said photoresist.

12. The method of claim 11, further comprising:
varying photo tolerance during said step of forming said emitter pedestal to minimize mis-alignment between the second polysilicon layer in said emitter pedestal and said emitter opening.

13. A heterojunction bipolar transistor, comprising:
a collector region;
a SiGe base region;
an emitter stack overlying said collector region, said emitter stack including an emitter opening filled with T-shaped polysilicon, said T-shaped polysilicon overlying nitride regions included in said stack; and
extrinsic base regions arranged on respective sides of said emitter stack, said extrinsic base regions being aligned with said emitter polysilicon region but not being directly aligned with said emitter opening.

14. The transistor of claim 13, wherein said extrinsic base regions are made from SiGe polysilicon.

15. The transistor of claim 13, wherein one of said extrinsic base regions is longer than another of said extrinsic base regions, and wherein a base contact is formed on the longer extrinsic base region.

16. The transistor of claim 13, wherein said reach-through collector region, emitter stack, and extrinsic base regions are contacted using mid-end-of-line collector, emitter, and base contact contacts respectively.
